(19) United States
(12) Patent Application Publication
(10) Pub. No.: US 2026/0304733 A1
(43) Pub. Date: Oct. 1, 2026

(54) MEMORY CELL HAVING THREE-DIMENSIONAL STRUCTURE, OPERATING METHOD THEREOF, AND MEMORY DEVICE

(71) Applicant: Foundation for Research and Business, Seoul National University of Science and Technology, Seoul (KR)

(72) Inventors: Wonbo SHIM, Seoul (KR); Kwangsoo KIM, Seoul (KR)

(73) Assignee: Foundation for Research and Business, Seoul National University of Science and Technology, Seoul (KR)

(21) Appl. No.: 19/304,385

(22) Filed: Aug. 19, 2025

(30) Foreign Application Priority Data
Mar. 28, 2025 (KR) 10-2025-0040605

(51) Int. Cl. H10B 12/00; G11C 11/405; G11C 11/4096

(52) U.S. Cl. CPC H10B 12/00; G11C 11/405; G11C 11/4096

(57) ABSTRACT

A memory cell having a 3D structure, an operating method thereof, and a memory device include a write complementary field effect transistor (CFET) in a gate-all-around (GAA) structure, including a first metal-oxide-semiconductor field-effect transistor (MOSFET) and a second MOSFET, a read CFET in a GAA structure, including a third MOSFET and a fourth MOSFET disposed adjacent in a horizontal direction from the write CFET, and a first connecting metal that forms a storage node by connecting a drain or a source of the first MOSFET and a gate of the read CFET.

### CROSS-REFERENCE TO RELATED APPLICATION

This application claims the benefit of Korean Patent Application No. 10-2025-0040605, filed on Mar. 28, 2025, in the Korean Intellectual Property Office, the entire disclosure of which is incorporated herein by reference for all purposes.

### BACKGROUND

### 1. Field of the Invention

One or more embodiments relate to a memory cell that includes a read complementary field effect transistor (CFET) including an enhancement and depletion transistors, and a write transistor, and forms a storage node by connecting the read CFET and the write transistor.

### 2. Description of the Related Art

Artificial intelligence (AI) semiconductors may be seen as non-memory semiconductors specialized in terms of efficiency that execute large-scale operations required for AI service implementation at ultra-high speed and ultra-low power. Central processing units (CPUs) and graphics processing units (GPUs) may process AI operations, but since the CPUs and GPUs are not developed for AI operations, the performance thereof may be wasted in areas other than the AI operations and inefficiencies such as cost and power consumption may occur. Accordingly, Al-specific semiconductors may be used to complement the limitations of basic semiconductors for AI operations (e.g., excessive power consumption or reduced operation efficiency). Although the AI semiconductors have low generality, the Al semiconductors may exhibit optimal power consumption and a rapid processing speed for AI data processing as the AI semiconductors are optimized for AI algorithms.

In the field of memory semiconductors, technology development for memory semiconductors for AI data processing is also taking place along with the technology development for the AI semiconductors. The amount of data exchanged between a CPU and a memory for AI data processing may increase, which may frequently cause latency in task processing. This may imply that a bottlenecked phenomenon may occur when retrieving information from the memory although the CPU processes tasks quickly. To solve such problems, the technologies such as a high bandwidth memory (HBM), process near memory (PNM), processing-in-memory (PIM), and computing in memory (CIM) are being developed in the field of the memory semiconductors. The HBM may refer to a technology that increases channels between the CPU and the memory. In addition, the PIM may refer to a technology where a CPU and a memory are present within a single electronic package, while the CIM may refer to a technology where a CPU and a memory are combined.

The above description has been possessed or acquired by the inventor(s) in the course of conceiving the present disclosure and is not necessarily an art publicly known before the present application is filed.

### SUMMARY

A memory cell having a three-dimensional (3D) structure, an operating method thereof, and a memory device according to an embodiment may form 3T0C having a complementary field effect transistor (CFET) structure, and form a read transistor complementarily in a depletion type and an enhancement type.

However, the technical aspects are not limited to the aforementioned aspects, and other technical aspects may be present.

According to an aspect, there is provided a memory cell having a 3D structure including a write CFET in a gate-all-around (GAA) structure, including a first metal-oxide-semiconductor field-effect transistor (MOSFET) and a second MOSFET, a read CFET in a GAA structure, including a third MOSFET and a fourth MOSFET disposed adjacent in a horizontal direction from the write CFET, and a first connecting metal that forms a storage node by connecting a drain or a source of the first MOSFET and a gate of the read CFET.

One of the first MOSFET and the second MOSFET may be p type and the other one may be n type.

One of the third MOSFET and the fourth MOSFET may be an enhancement type, the other one may be a depletion type, one of the third MOSFET and the fourth MOSFET may be a p type, and the other one may be an n type.

According to another aspect, there is provided a method of operating the memory cell having the 3D structure, wherein a voltage is applied to a gate of the write CFET by a write operation, a write voltage is applied to a source or a drain of the first MOSFET or the second MOSFET, where a first write metal is formed, and a value for the write voltage is stored in a capacitor of the storage node, and a voltage is applied to a source or a drain of the third MOSFET by a read operation, and a change in a current flowing from a source or a drain of the fourth MOSFET is detected.

According to another aspect, there is provided a memory device including a word line configured with each of a plurality of first word lines and a plurality of second word lines, a bit line configured with each of a plurality of first bit lines and a plurality of second bit lines, and a memory cell array configured with a plurality of memory cells, the memory cell including a write CFET including a first MOSFET and a second MOSFET having a source or drain region connected to one of the plurality of first bit lines and including a gate connected to one of the plurality of first word lines, a read CFET including a third MOSFET having a drain or source region connected to one of the plurality of second word lines and a fourth MOSFET having a source or drain region connected to one of the plurality of second bit lines, in which a storage node is formed by connecting the drain or source region of the first MOSFET or the second MOSFET and a gate of the read CFET.

Additional aspects of embodiments will be set forth in part in the description which follows and, in part, will be apparent from the description, or may be learned by practice of the disclosure.

According to embodiments, a memory cell having a 3D structure, an operating method thereof, and a memory device according to an embodiment form 3T0C having a CFET structure, and complementarily form a read transistors in a depletion type and an enhancement type, thereby improving read characteristics of the memory cell (e.g., output characteristics of the read current according to the data fluctuation) and achieving high accuracy of AI operations in a processing-in-memory (PIM). Accordingly, it may be possible to reduce the number of refresh operations, improve power efficiency, and also achieve high integration structurally because of easy scaling.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 illustrates an example of a circuit diagram of a two-transistor zero-capacitor dynamic random access memory (2T0C DRAM) unit cell;

FIG. 2A illustrates an example of a perspective view of a 2T0C DRAM unit cell, and FIG. 2B illustrates an example of a graph of characteristics of an enhancement N-type metal-oxide-semiconductor (NMOS);

FIG. 3 is a perspective view of a memory cell having a three-dimensional (3D) structure according to an embodiment;

FIG. 4 illustrates an example of cross-sections A-A′, B-B′, and C-C′ of a memory cell having a 3D structure according to an embodiment;

FIG. 5 illustrates an example of a channel layer in a cross-section C-C′ of a memory cell having a 3D structure according to an embodiment;

FIG. 6A is a perspective view of a memory cell having a 3D structure according to another embodiment, and FIG. 6B illustrates an example of a cross-section D-D′ of a memory cell having a 3D structure according to another embodiment;

FIG. 7 is a circuit diagram of a memory device including a memory cell having a 3D structure according to an embodiment; and

FIG. 8A is a graph of characteristics of a read complementary field effect transistor (CFET) of a memory cell in a memory device according to an embodiment, and FIG. 8B is a graph of a current variation according to a voltage between 2T0C and a memory cell of a memory device according to an embodiment.

### DETAILED DESCRIPTION

The following detailed structural or functional description is provided as an example only and various alterations and modifications may be made to the embodiments. Accordingly, the embodiments are not construed as limited to the disclosure and should be understood to include all changes, equivalents, and replacements within the idea and the technical scope of the disclosure.

Although terms, such as first, second, and the like are used to describe various components, the components are not limited to the terms. These terms should be used only to distinguish one component from another component. For example, a first component may be referred to as a second component, or similarly, the second component may be referred to as the first component.

It should be noted that if it is described that one component is “connected,” “coupled,” or “joined” to another component, a third component may be “connected,” “coupled,” and “joined” between the first and second components, although the first component may be directly connected, coupled, or joined to the second component.

As used herein, the singular form is intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms, including technical and scientific terms, used herein have the same meaning as commonly understood by one of ordinary skill in the art to which this disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. When describing the embodiments with reference to the accompanying drawings, like reference numerals refer to like elements and a repeated description related thereto will be omitted.

Artificial intelligence (AI) algorithms are widely used in various fields such as image recognition, voice recognition, chatbots, and the like. These AI algorithms perform AI operations that require large-scale data processing, and the performance of AI operations is also rapidly developing as the amount of data increases exponentially to meet the increasing demand. For example, a computing architecture may typically use the von Neumann architecture for operations. The von Neumann architecture may perform operations by exchanging data between a processor and a memory using a bus. However, since the AI operations are operated using a large amount of data, the von Neumann architecture may cause a lot more data to be exchanged than general data operations. This implies that the von Neumann architecture is inefficient in terms of time and power consumption for AI operations, and thus, a computing structure more suitable for AI operations has been required.

As an alternative, a processing-in-memory (PIM) computing architecture has been proposed. The PIM may minimize data exchange because the PIM may store and operate data within the memory. Accordingly, the PIM may be suitable for AI operations that process a large amount of data and may be more efficient than the von Neumann architecture in terms of time and power consumption. As memory devices used in the PIM, a static random-access memory (SRAM), a dynamic random access memory (DRAM), or the like may be used, and a DRAM, which has high integration and may achieve high throughput, is a candidate, since an SRAM has limited capacity due to low integration. In addition, since a DRAM has high throughput, the DRAM may secure high-speed operations and low power in Al operations that process a large amount of data so as to be used more effectively.

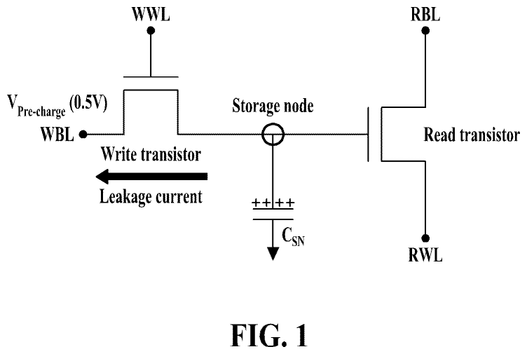

FIG. 1 illustrates an example of a circuit diagram of a two-transistor zero-capacitor (2T0C) DRAM unit cell.

The 2T0C DRAM unit cell may include two transistors (e.g., a write transistor and a read transistor) without a capacitor. Unlike a 1T1C DRAM, in the 2T0C DRAM, the read transistor and the write transistor are separately present. Therefore, data loss may be prevented during a read operation, relatively high-speed operations may be performed, and the advantage of low power consumption may be obtained, making the 2T0C DRAM suitable for AI operations. In addition, in the 2T0C DRAM unit cell, a gate of the read transistor may be connected to a drain of the write transistor. A storage node SN may be formed between the connected write transistor and read transistor. The 2T0C DRAM unit cell may store and read data (e.g., a charge or a weight) through parasitic capacitance CsN present in the storage node. When the write transistor records data on the storage node, the read transistor may output a constant “read current,” read a value thereof based on the stored data, and perform an AI operation.

However, the 2T0C DRAM, which is a volatile element, loses the charge (e.g., data) stored in the storage node over time due to a leakage current after storing data. The loss of charge (e.g., data fluctuation) may disturb the AI operation from maintaining a realistically constant read current (I_{READ}), which may be the most important reason of lowering the accuracy of the AI operation. Accordingly, the 2T0C DRAM memory may perform a refresh operation that re-writes data at regular intervals to maintain high accuracy. Since such a refresh operation is a major factor in generating additional power consumption, a solution that maximizes a refresh cycle may be applied. However, before increasing the refresh cycle to achieve good performance in terms of energy efficiency, it is necessary to sufficiently secure Al operation accuracy according to data fluctuations.

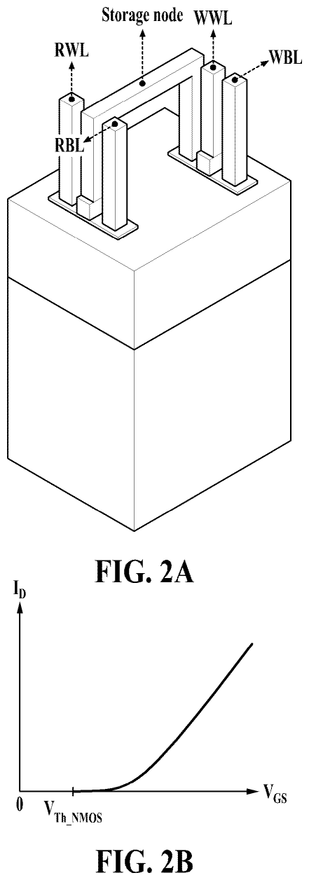

FIG. 2A illustrates an example of a perspective view of a 2T0C DRAM unit cell, and FIG. 2B illustrates an example of a graph of characteristics of an enhancement N-type metal-oxide-semiconductor (NMOS).

As illustrated in FIG. 2A, the 2T0C DRAM unit cell may use an enhancement NMOS having a planar structure as the read/write transistor. In the 2T0C DRAM unit cell, the storage node may be formed on a metal connecting the drain of the write transistor and the gate of the read transistor. As illustrated in FIG. 2B, in the enhancement NMOS, as the data (e.g., a gate voltage V_{g}) stored in the storage node decreases due to the leakage current, a read current I_{d} may decrease. This variability of the read current implies a decrease in accuracy in the AI operation, and thus, it is necessary to minimize the variability in the current due to data fluctuations.

In addition, the amount of data in AI models, which increases exponentially every year, requires more devices in chips of the same size in terms of memory performance and economy. In this regard, the 2T0C DRAM having a planar structure may have a risk in terms of device integration. Therefore, devices that may perform high-performance in AI operations are required to have low variability in the read current due to fluctuations in data (e.g., voltage) and a physical device structure that may achieve high integration.

Accordingly, a memory cell having a 3D structure, an operating method thereof, and a memory device according to an embodiment form 3T0C having a complementary field effect transistor (CFET) structure, and complementarily form the read transistors in a depletion type and an enhancement type, thereby improving read characteristics of the memory cell (e.g., output characteristics of the read current according to the data fluctuation) and achieving high accuracy of the AI operation in the PIM. Accordingly, it may be possible to reduce the number of refresh operations, improve power efficiency, and also achieve high integration structurally because of easy scaling.

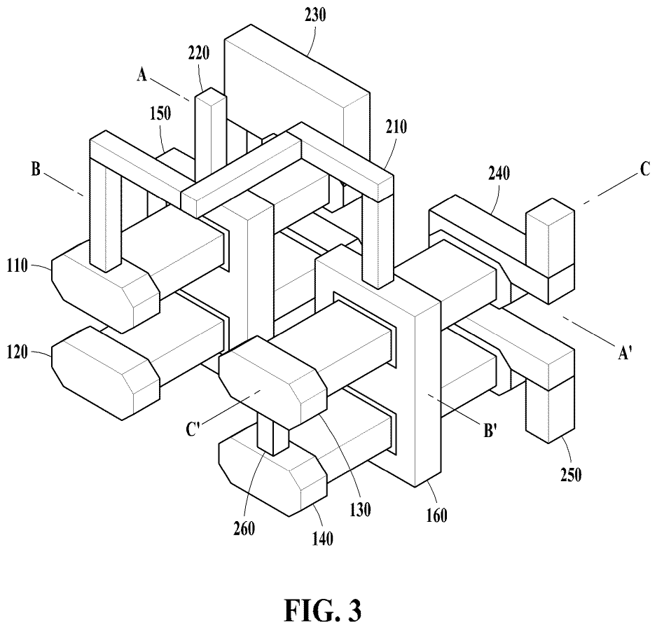

FIG. 3 is a perspective view of a memory cell having a 3D structure according to an embodiment.

A memory cell 10 may include a write CFET in a gate-all-around (GAA) structure, including a first metal-oxide-semiconductor field-effect transistor (MOSFET) 110 and a second MOSFET 120, a read CFET in a GAA structure, including a third MOSFET 130 and a fourth MOSFET 140 disposed adjacent in a horizontal direction from the write CFET, and a first connecting metal 210 that forms a storage node by connecting a drain or a source of the first MOSFET 110 and a gate 160 of the read CFET.

The memory cell 10 may be formed as a CFET in a GAA structure, in which the gate surrounds all sides of the channel to overcome the physical limitations of the device. In addition, the CFET may be a monolithic structure with an NMOS or a p-type MOS (PMOS) on the top and a PMOS or an NMOS on the bottom, sharing the gate.

In the write CFET, one of the first MOSFET 110 and the second MOSFET 120 may be the p-type and the other one thereof may be the n-type. For example, when the first MOSFET 110 is the n-type, the NMOS, the second MOSFET 120 may be the p-type, the PMOS, and when the first MOSFET 110 is the p-type, the PMOS, the second MOSFET 120 may be the n-type, the NMOS.

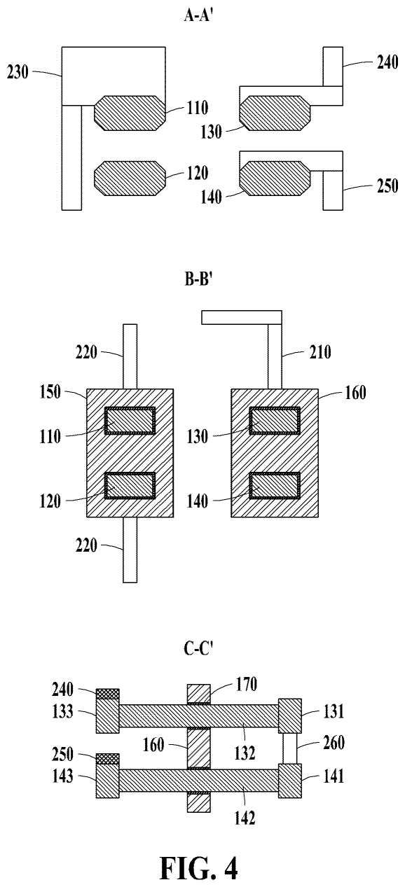

FIG. 4 illustrates an example of cross-sections A-A′, B-B′, and C-C′ of a memory cell having a 3D structure according to an embodiment.

The cross-section A-A′ may be parallel to a transverse axis of the memory cell 10 and may illustrate one side of the memory cell 10 including a metal that is connected to external lines (e.g., word lines and bit lines). The cross-section B-B′ may be parallel to the cross-section A-A′ and may illustrate an internal cross-section of a gate 150 of the write CFET and the gate 160 of the read CFET of the memory cell 10. The cross-section C-C′ may be perpendicular to the cross-sections A-A′ and B-B′ and may illustrate an internal cross-section of the read CFET.

The write CFET may use one of the first MOSFET 110 and the second MOSFET 120. As shown in the left configuration of the cross-section A-A′ of FIG. 4, the configuration used may include a first write metal 230 connected to a write bit line WBL. This may imply that one of the first MOSFET and the second MOSFET used includes the first write metal extending from an upper surface of a drain or a source of the one of the first MOSFET and the second MOSFET used, to be connected to the write bit line. For example, when the first MOSFET 110 is used as the write CFET, the first write metal 230 may be formed on the first MOSFET 110 and connected to the write bit line WBL. On the other hand, when the second MOSFET 120 is used as the write CFET, the first write metal 230 may be formed on the second MOSFET 120 and connected to the write bit line WBL. In addition, when the NMOS is used as the write CFET, a drain of the NMOS may be connected to the write bit line WBL, and a source of the NMOS may be connected to the first connecting metal 210 forming the storage node. In contrast, when the PMOS is used as the write CFET, a source of the PMOS may be connected to the write bit line WBL, and a drain of the PMOS may be connected to the first connecting metal 210 forming the storage node.

In addition, as shown in the left configuration of the cross-section B-B′ of FIG. 4, the first MOSFET 110 and the second MOSFET 120 may be formed in a form in which the first MOSFET 110 and the second MOSFET 120 are sequentially stacked and fit into the write gate 150 positioned vertically with respect to bodies of the first MOSFET 110 and the second MOSFET 120. The write gates 150 may include a second write metal 220 extending from an upper surface and a lower surface to be connected to the write word line WWL.

In the read CFET, one of the third MOSFET 130 and the fourth MOSFET 140 may be an enhancement type, the other one may be a depletion type, one of the third MOSFET 130 and the fourth MOSFET 140 may be a p type, and the other one may be an n type. For example, when the third MOSFET 130 is the enhancement NMOS, the fourth MOSFET 140 may be a depletion PMOS, and when the third MOSFET 130 is an enhancement PMOS, the fourth MOSFET 140 may be a depletion NMOS. In addition, when the third MOSFET 130 is the depletion NMOS, the fourth MOSFET 140 may be the enhancement PMOS, and when the third MOSFET 130 is the depletion PMOS, the fourth MOSFET 140 may be the enhancement NMOS. Through this, the memory cell 10 may also secure design expandability.

As shown in the right configuration of the cross-section A-A′ of FIG. 4, the third MOSFET 130 may include a first read metal 240 extending upward in a bent or non-bent form from an upper surface of a source or drain region to be connected to a read word line (RWL). In addition, the fourth MOSFET 140 may include a second read metal 250 extending downward in a bent or non-bent form from an upper surface of a source or drain region to be connected to the read bit line RBL.

In addition, as shown in the right configuration of the cross-section B-B′ of FIG. 4, the third MOSFET 130 and the fourth MOSFET 140 may be formed in a form in which the third MOSFET 130 and the fourth MOSFET 140 are sequentially stacked and fit into the gate 160 of the read CFET positioned vertically with respect to bodies of the third MOSFET 130 and the fourth MOSFET 140. The gate 160 of the read CFET 160 may be in contact with the first connecting metal 210 so as to be connected to the drain or the source of the first MOSFET 110 on the upper surface.

As shown in the cross-section C-C′ of FIG. 4, the third MOSFET 130 and the fourth MOSFET 140 may be connected through a second connecting metal 260. In addition, the third MOSFET 130 and the fourth MOSFET 140 may include a first channel layer 132 and a second channel layer 142 sequentially stacked between the gate 160 of the read CFET. The third MOSFET 130 and the fourth MOSFET 140 may include an insulating layer 170 between the gate 160 of the read CFET and each of the first channel layer 132 and the second channel layer 142. In addition, the third MOSFET 130 and the fourth MOSFET 140 may include source and/or drain regions 131, 141, 133, and 143, which are electrical contact points formed by extending from the first channel layer 132 and the second channel layer 142 through an epitaxial growth process. In addition, the first MOSFET 110 and the second MOSFET 120 may also include a channel layer, and a source region and a drain region, which are electrical contact points formed by extending from the channel layer through an epitaxial growth process. In addition, the first channel layer 132, the second channel layer 142, and the source and/or drain regions 131, 141, 133, and 143 may be formed of silicon (Si), the gate 160 of the read CFET may be formed of silicon germanium (SiGe), and the insulating layer 170 may be formed of a high-k material.

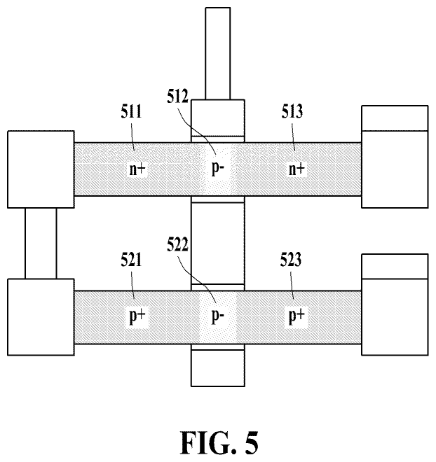

FIG. 5 illustrates an example of a channel layer in a cross-section C-C′ of a memory cell having a 3D structure according to an embodiment.

For example, when the third MOSFET 130 is the enhancement NMOS, the first channel layer 132 may include a first source doped region 511, a first channel doped region 512, and a first drain doped region 513. The first source doped region 511 and the first drain doped region 513 may include arsenic (As) doped at a high concentration based on the n type, and the first channel doped region 512 may include boron (B) doped at a relatively low concentration based on the p type. When the fourth MOSFET 140 is the depletion PMOS in response to the third MOSFET 130, the second channel layer 142 may include a second drain doped region 521, a second channel doped region 522, and a second source doped region 523. The second drain doped region 521 and the second source doped region 523 may include B doped at a high concentration based on the p type, and the second channel doped region 522 is a depletion channel and may include B doped at a relatively low concentration based on the p type.

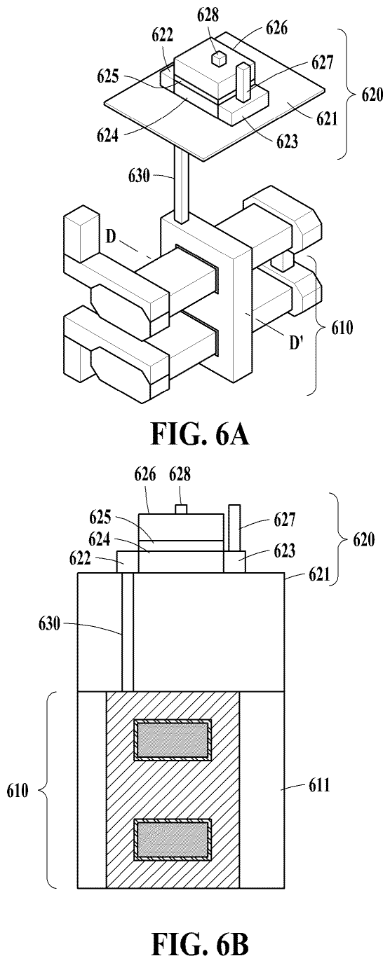

FIG. 6A is a perspective view of a memory cell having a 3D structure according to another embodiment, and FIG. 6B illustrates an example of a cross-section D-D′ of a memory cell having a 3D structure according to another embodiment.

A memory cell 20 according to another embodiment may include a read CFET 610 having a GAA structure including a first MOSFET and a second MOSFET, a write transistor 620 positioned on an upper portion of the read CFET 610 and including an oxide channel layer containing an channel region 624 (e.g., oxide semiconductor material) on a first insulating layer 621, and a third connecting metal 630 forming a storage node by connecting a gate of the read CFET 610 and one of source and/or drain regions 622 and 623 of the write transistor 620. The first MOSFET and the second MOSFET may be formed in a form in which the first MOSFET and the second MOSFET are sequentially stacked and fit into a read gate positioned vertically with respect to bodies of the first MOSFET and the second MOSFET. One of the first MOSFET and the second MOSFET may be the enhancement type, the other one may be the depletion type, one of the first MOSFET and the second MOSFET may be the p type, and the other one may be the n type.

The first insulating layer 621 and a periphery 611 of the read CFET 610 may be filled with an insulating composition that insulates them from the outside. For example, the first insulating layer 621 and the periphery 611 of the read CFET 610 may contain oxide. In addition, as shown in FIG. 6B, the first insulating layer 621 may be formed in a region from an uppermost end of the read CFET 610 to a bottom surface where the oxide channel layer is formed, excluding the third connecting metal 630. Accordingly, the memory cell 20 may be formed in a form in which the read CFET 610 and the source region 622 are electrically connected through the third connecting metal 630 while the read CFET 610 and the third connecting metal 630 are insulated from the outside through the periphery 611 and the first insulating layer 621.

The read CFET 610 may have the same configuration as the read CFET including the third MOSFET 130 and the fourth MOSFET 140 described above with reference to FIGS. 3 to 5. The write transistor 620 may include the first insulating layer 621, an oxide channel layer including the source and/or drain regions 622 and 623 and the channel region 624, a second insulating layer 625, and a gate layer 626. For example, the channel region 624 may be an oxide semiconductor containing indium gallium zinc oxide (IGZO), indium tin oxide (ITO), indium tungsten oxide (IWO), and the like. In addition, when the region 623 among the source and/or drain regions 622 and 623 is a drain region, the write transistor 620 may include a third write metal 627 that extends from the drain region 623 to be connected to the write bit line WBL. Also, the write transistor 620 may include a fourth write metal 628 that extends from an upper surface of the gate layer 626 to be connected to the write word line WWL.

The memory cell 10 and the memory cell 20 described above may have a higher integration than in the planar structure shown in FIG. 2, and may also have a reduced variability of the read current than in the planar structure.

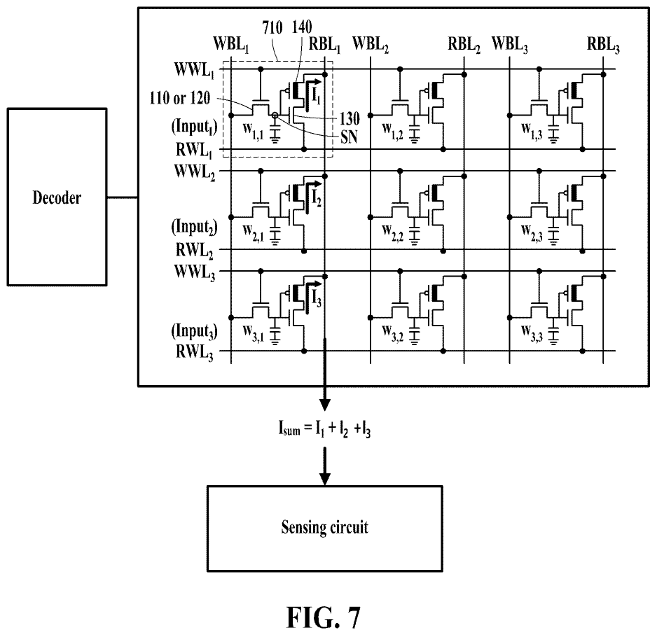

FIG. 7 is a circuit diagram of a memory device including a memory cell having a 3D structure according to an embodiment.

The memory device may include a word line configured with each of a plurality of first word lines WWL and a plurality of second word lines RWL, and a bit line configured with each of a plurality of first bit lines WBL and a plurality of second bit lines RBL. In addition, the memory device may include a memory cell array configured with a plurality of memory cells, the memory cell including a write CFET including the first MOSFET 110 and the second MOSFET 120 having a source or drain region connected to one first bit line WBL of the plurality of first bit lines and including a gate connected to one first word line WWL of the plurality of first word lines, a read CFET including the third MOSFET 130 having a drain or source region connected to one second word line RWL of the plurality of second word lines and the fourth MOSFET 140 having a source or drain region connected to one second bit line RBL of the plurality of second bit lines, in which a storage node SN is formed by connecting the drain or source region of the first MOSFET 110 or the second MOSFET 120 and a gate of the read CFET.

The memory device may perform a write operation and a read operation of the memory cells by controlling a decoder and a sensing circuit. In the memory cell, a voltage may be applied to the gate of the write CFET by the write operation, and a write voltage may be applied to the source or drain of the first MOSFET or the second MOSFET on which a first write metal is formed so that a value for the write voltage may be stored in parasitic capacitor Cp of the storage node SN. For example, when the write operation is performed on a first memory cell 710, the decoder may first apply 0 (zero) V, positive, or negative voltage to a first write word line WWL₁. Then, the decoder may apply a value corresponding to the write voltage of 0 (zero) or 1 (one) to a first write bit line WBL₁ so that the value is stored in the capacitor of the storage node SN. The decoder may select a row and a column of the memory cell array and apply a voltage thereto. Without being limited thereto, for example, the decoder may be divided into a row decoder and a column decoder.

In addition, the memory device may use one of the first MOSFET or the second MOSFET in the write CFET. When one of the first MOSFET and the second MOSFET used is the n type, the drain of one of the first MOSFET and the second MOSFET may be connected to the first bit line. The source of one of the first MOSFET and the second MOSFET may be connected to a first connecting metal that is connected to the read CFET to form the storage node. In contrast, when one of the first MOSFET and the second MOSFET used is the p type, the source of one of the first MOSFET and the second MOSFET may be connected to the first bit line, and the drain of one of the first MOSFET and the second MOSFET may be connected to the first connecting metal.

In addition, in the memory cell, a voltage may be applied to the source or drain of the third MOSFET 130 by the read operation, and a change in the current flowing from the source or drain of the fourth MOSFET 140 may be detected. For example, when the write operation is performed on the first memory cell 710, the decoder may first apply 0 (zero)V, positive, or negative voltage to the first read word line RWL₁. Then, the sensing circuit may sense a current I₁ corresponding to the product of the applied voltage and conductance (e.g., a reciprocal of resistance) within the memory cell. The sensing circuit may include a multiplexer MUX and a sense amplifier. However, since the memory device according to an embodiment generally performs a large amount of operations as it is utilized in a PIM element, the voltage may be applied to a plurality of read word lines RWL₁, RWL₂, and RWL₃, and the sum of currents I₁, I₂, and I₃ flowing through each bit line (e.g., a read bit line RBL₁ may be sensed by the decoder and the sensing circuit. On the other hand, in the memory cell, the voltage may be applied to the source or drain of the fourth MOSFET 140 by the read operation, and a change in the current flowing from the source or drain of the third MOSFET 130 may be detected.

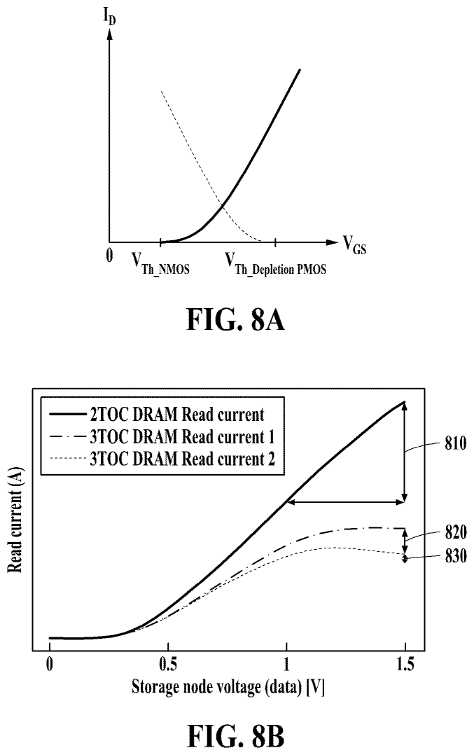

FIG. 8A is a graph of characteristics of a read CFET of a memory cell in a memory device according to an embodiment, and FIG. 8B is a graph of a current variation according to a voltage between 2T0C and a memory cell of a memory device according to an embodiment.

In FIG. 8A, the memory device may include a depletion PMOS with a characteristic that a current is inversely proportional to a voltage decrease and complement the characteristics thereof when the read CFET of the memory cell includes an enhancement NMOS so that the current is not proportional to the voltage decrease over time. In addition, in FIG. 8B, it may be confirmed that the current variability is greatly reduced when the voltages with respect to the 2T0C and the memory cell of the memory device according to an embodiment are reduced to 1.5 V to 1 V in the same manner. Accordingly, the memory device according to an embodiment may minimize the current variability by configuring two MOSFETS complementarily for the read CFET, thereby securing the accuracy of the AI operations that sense and process the sum of currents.

The embodiments described herein may be implemented using a hardware component, a software component and/or a combination thereof. A processing device may be implemented using one or more general-purpose or special-purpose computers, such as, for example, a processor, a controller, an arithmetic logic unit (ALU), a digital signal processor (DSP), a microcomputer, an FPGA, a programmable logic unit (PLU), a microprocessor or any other device capable of responding to and executing instructions in a defined manner. The processing device may run an OS and one or more software applications that run on the OS. The processing unit also may access, store, manipulate, process, and generate data in response to execution of the software. For purpose of simplicity, the description of a processing device is used as singular; however, one skilled in the art will appreciate that a processing device may include multiple processing elements and/or multiple types of processing elements. For example, the processing device may include a plurality of processors, or a single processor and a single controller. In addition, different processing configurations are possible, such as parallel processors.

The software may include a computer program, a piece of code, an instruction, or some combinations thereof, to independently or collectively instruct or configure the processing device to operate as desired. Software and data may be stored in any type of machine, component, physical or virtual equipment, or computer storage medium or device capable of providing instructions or data to or being interpreted by the processing device. The software may also be distributed over network-coupled computer systems so that the software is stored and executed in a distributed fashion. The software and data may be stored by one or more non-transitory computer-readable recording mediums.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as compact disc read-only memory (CD-ROM) discs and digital video discs (DVDs); magneto-optical media such as floptical disks; and hardware devices that are specifically configured to store and perform program instructions, such as ROM, random access memory (RAM), flash memory, and the like. Examples of program instructions include both machine code, such as produced by a compiler, and files containing higher-level code that may be executed by the computer using an interpreter.

The above-described hardware devices may be configured to act as one or more software modules in order to perform the operations of the above-described embodiments, or vice versa.

As described above, although the embodiments have been described with reference to the limited drawings, a person skilled in the art may apply various technical modifications and variations based thereon. For example, suitable results may be achieved if the described techniques are performed in a different order, and/or if components in a described system, architecture, device, or circuitry are combined in a different manner, or replaced or supplemented by other components or their equivalents.

Therefore, other implementations, other embodiments, and equivalents to the claims are also within the scope of the following claims.

1. A memory cell comprising:
a write complementary field effect transistor (CFET) in a gate-all-around (GAA) structure, comprising a first metal-oxide-semiconductor field-effect transistor (MOSFET) and a second MOSFET;
a read CFET in a GAA structure, comprising a third MOSFET and a fourth MOSFET disposed adjacent in a horizontal direction from the write CFET; and
a first connecting metal that forms a storage node by connecting a drain or a source of the first MOSFET and a gate of the read CFET.

2. The memory cell of claim 1, wherein the memory cell uses one of the first MOSFET and the second MOSFET in the write CFET.

3. The memory cell of claim 2, wherein the one of the first MOSFET and the second MOSFET used comprises a first write metal extending from an upper surface of a drain or a source of the one of the first MOSFET and the second MOSFET to be connected to a write bit line.

4. The memory cell of claim 1, wherein
the first MOSFET and the second MOSFET are formed in a form in which the first MOSFET and the second MOSFET are sequentially stacked and fit into a write gate positioned vertically with respect to bodies of the first MOSFET and the second MOSFET, and
the third MOSFET and the fourth MOSFET are formed in a form in which the third MOSFET and the fourth MOSFET are sequentially stacked and fit into a read gate positioned vertically with respect to bodies of the third MOSFET and the fourth MOSFET.

5. The memory cell of claim 4, wherein the write gate comprises second write metals extending individually from an upper surface and a lower surface to be connected to a write word line.

6. The memory cell of claim 4, wherein the read gate is in contact with the first connecting metal so as to be connected to the drain or the source of the first MOSFET on an upper surface.

7. The memory cell of claim 1, wherein one of the first MOSFET and the second MOSFET is a p type and the other one is an n type.

8. The memory cell of claim 1, wherein
the third MOSFET comprises a first read metal extending upward in a bent or non-bent form from an upper surface of a source or drain region to be connected to a read word line, and
the fourth MOSFET comprises a second read metal extending downward in a bent or non-bent form from an upper surface of a source or drain region to be connected to a read bit line.

9. The memory cell of claim 1, wherein one of the third MOSFET and the fourth MOSFET is an enhancement type, the other one is a depletion type, one of the third MOSFET and the fourth MOSFET is a p type, and the other one is an n type.

10. The memory cell of claim 1, wherein the first MOSFET, the second MOSFET, the third MOSFET, and the fourth MOSFET comprise a channel layer, and a source region and a drain region, which are electrical contact points formed by extending from the channel layer through an epitaxial growth process.

11. A method of operating the memory cell of claim 1, wherein
a voltage is applied to a gate of the write CFET by a write operation,
a write voltage is applied to a source or a drain of the first MOSFET or the second MOSFET, and a value for the write voltage is stored in a capacitor of the storage node, and
a voltage is applied to a source or a drain of the third MOSFET by a read operation, and a change in a current flowing from a source or a drain of the fourth MOSFET is detected, or a voltage is applied to the source or the drain of the fourth MOSFET and a change in a current flowing from the source or the drain of the third MOSFET is detected.

12. A memory device comprising:
a word line configured with each of a plurality of first word lines and a plurality of second word lines;
a bit line configured with each of a plurality of first bit lines and a plurality of second bit lines; and
a memory cell array configured with a plurality of memory cells, the memory cell comprising a write complementary field effect transistor (CFET) comprising a first metal-oxide-semiconductor field-effect transistor (MOSFET) and a second MOSFET having a source or drain region connected to one of the plurality of first bit lines and comprising a gate connected to one of the plurality of first word lines, a read CFET comprising a third MOSFET having a drain or source region connected to one of the plurality of second word lines and a fourth MOSFET having a source or drain region connected to one of the plurality of second bit lines, in which a storage node is formed by connecting the drain or source region of the first MOSFET or the second MOSFET and a gate of the read CFET.

13. The memory device of claim 12, wherein the memory device uses one of the first MOSFET and the second MOSFET in the write CFET.

14. The memory device of claim 13, wherein
when one of the first MOSFET and the second MOSFET used is of an n type, a drain of the one of the first MOSFET and the second MOSFET is connected to the first bit line, and a source of the one of the first MOSFET and the second MOSFET is connected to a first connecting metal which is connected to the read CFET to form the storage node, and
when one of the first MOSFET and the second MOSFET used is of a p type, a source of the one of the first MOSFET and the second MOSFET is connected to the first bit line, and a drain of the one of the first MOSFET and the second MOSFET is connected to the first connecting metal.

15. A memory cell comprising:
a read complementary field effect transistor (CFET) in a gate-all-around (GAA) structure comprising a first metal-oxide-semiconductor field-effect transistor (MOSFET) and a second MOSFET;
a write transistor comprising an oxide channel layer and positioned on a first insulating layer which is an upper portion of the read CFET; and
a third connecting metal that forms a storage node by connecting a gate of the read CFET and one of a source or drain region of the write transistor.

16. The memory cell of claim 15, wherein
the first MOSFET and the second MOSFET are formed in a form in which the first MOSFET and the second MOSFET are sequentially stacked and fit into a read gate positioned vertically with respect to bodies of the first MOSFET and the second MOSFET.

17. The memory cell of claim 15, wherein one of the first MOSFET and the second MOSFET is an enhancement type, the other one is a depletion type, one of the first MOSFET and the second MOSFET is a p type, and the other one is an n type.

18. The memory cell of claim 15, wherein the first insulating layer is formed in a region from an uppermost end of the read CFET to a bottom surface where the oxide channel layer is formed, excluding the third connecting metal.

19. The memory cell of claim 15, wherein the oxide channel layer comprises an oxide semiconductor material, which is one of indium gallium zinc oxide (IGZO), indium tin oxide (ITO), and indium tungsten oxide (IWO).

20. The memory cell of claim 15, further comprising:
a third write metal extending from an upper surface of a region of the remaining one of the source or drain region of the write transistor to be connected to a write bit line, and a fourth write metal extending from an upper surface of a gate layer of the write transistor to be connected to a write word line.
